(19) United States
(12) Patent Application Publication
(10) Pub. No.: US 2024/0220853 A1
(43) Pub. Date: Jul. 4, 2024

(54) SRAM READ YIELD TRAINING METHOD, SRAM READ YIELD PREDICTION METHOD AND COMPUTING APPARATUS

(71) Applicant: UIF (University Industry Foundation), Yonsei University, Seoul (KR)

(72) Inventors: Seong Ook JUNG, Seoul (KR); Sung Ho PARK, Seoul (KR); Gi Seok KIM, Seoul (KR); Won Joon JO, Seoul (KR)

(73) Assignee: UIF (University Industry Foundation), Yonsei University, Seoul (KR)

(21) Appl. No.: 18/110,458

(22) Filed: Feb. 16, 2023

(30) Foreign Application Priority Data
Dec. 28, 2022 (KR) 10-2022-0186689

(51) Int. Cl. G06N 20/00; G06N 5/04; G06N 7/01; G11C 11/419

(52) U.S. Cl. CPC G06N 20/00; G06N 5/04; G06N 7/01; G11C 11/419

(57) ABSTRACT

There is provided a method of training a multi-layer perceptron on a read access yield of a static random access memory (SRAM), the method including: a first training operation of performing training with a design parameter of the SRAM according to a read operation metric of the SRAM, training data according to the read operation metric of the SRAM, and a transistor level simulation result of the SRAM; a second training operation of performing training with the design parameter of the SRAM according to the read operation metric of the SRAM, the training data according to the read operation metric of the SRAM, and a layout level simulation result of the SRAM; and a third training operation of performing training with the design parameter of the SRAM according to the read operation metric of the SRAM, the training data according to the read operation metric of the SRAM, and a measurement result measured with a chip in which the SRAM is formed.

### CROSS-REFERENCE TO RELATED APPLICATION

This application claims priority to Korean Patent Application No. 10-2022-0186689 (filed on Dec. 28, 2022), which is hereby incorporated by reference in its entirety.

### BACKGROUND

The disclosure relates to a static random access memory (SRAM) read access yield training method, a SRAM read access yield prediction, and a computing apparatus.

Along with the development of process technology, the proportion of SRAMs used in system-on chips (SOC), microprocessors and the like is increasing. The size of and operating voltage of transistors continue to decrease, and thus the variations in device characteristics are intensified.

As a result, the margin for an SRAM to operate normally has decreased, limiting technology scaling. The variations in threshold voltage due to transistor size reduction have a great influence on determining the operating margin of the SRAM.

In the conventional SRAM manufacturing processes, high level design and verification through simulation are performed and only when a target performance metric is reached in the verification, low level design and verification are performed. In the related art, design, simulation and redesign processes are repeated a large number of times, and a great amount of manpower, time and cost are consumed until one finished product is formed.

The embodiment is intended to resolve the above described issues of the related art. In other words, the embodiment is directed to providing a method of rapidly predicting the yield of an SRAM.

### SUMMARY

The present embodiment includes a method of training a multi-layer perceptron on a read access yield of a static random access memory (SRAM), the method including: a first training operation of performing training with a design parameter of the SRAM according to a read operation metric of the SRAM, training data according to the read operation metric of the SRAM, and a transistor level simulation result of the SRAM; a second training operation of performing training with the design parameter of the SRAM according to the read operation metric of the SRAM, the training data according to the read operation metric of the SRAM, and a layout level simulation result of the SRAM; and a third training operation of performing training with the design parameter of the SRAM according to the read operation metric of the SRAM, the training data according to the read operation metric of the SRAM, and a measurement result measured with a chip in which the SRAM is formed.

According to an aspect of the present embodiment, as a result of the second training operation, a layer reflecting an effect of one or more of a parasitic resistance and a parasitic capacitance is generated in the multi-layer perceptron.

According to an aspect of the present embodiment, as a result of the third training operation, a layer reflecting an effect of a process is generated in the multi-layer perceptron.

According to an aspect of the present embodiment, the read operation metric includes a voltage deviation of a bit line pair, an offset voltage of a sense amplifier, and a detection time deviation of the sense amplifier.

According to an aspect of the present embodiment, training data according to the voltage deviation of the bit line pair is acquired from a probability distribution of a threshold voltage of a pass transistor of the SRAM, a probability distribution of a threshold voltage of a pull-down transistor of the SRAM, and a probability of a bit line voltage value.

According to an aspect of the present embodiment, training data according to the offset voltage of the sense amplifier and the detection time deviation of the sense amplifier includes a probability distribution computed as a mean and a standard deviation of offset voltage deviations of the sense amplifier following a Gaussian distribution, and a probability distribution computed as a mean and a standard deviation of detection time deviations of the sense amplifier following a Gaussian distribution.

According to an aspect of the present embodiment, the training data further includes a yield value computed by the following equation,

$${Y}_{R} = {\int }_{{T}_{WL 2 SAE}} {[ {\int }_{{V}_{OS}} {\{ 1 - {F}_{VBL} ( v \vert {T}_{WL 2 SAE} = 1 ) \}}^{{N}_{ROW} {N}_{COL , SA}} {f}_{VOS} ( v ) dv ]}^{{N}_{SA}} \times {f}_{TWL 2 SAE} ( t ) dt .$$

F_{VBL}(V|T_{WL2SAE}=t) is a probability that no voltage deviation occurs in the bit line pair as much as the offset voltage of the sense amplifier during the detection time of the detection amplifier.
f_{VOS}(v) is a probability that the sense amplifier succeeds in detection at an offset voltage.
f_{TWL2SAE}(t) is a probability that sensing is successful within a detection time of the sense amplifier.

The present embodiment includes a method of predicting a read access yield of a static read only memory (SRAM) using a trained multi-layer perceptron, the method including: inputting a transistor level simulation result of the SRAM, a layout level simulation result of the SRAM, and a measurement result measured with a chip in which the SRAM is formed into the multi-layer perceptron trained with the same design parameter of the SRAM and the same training data according to a read operation metric of the SRAM, together with the design parameter of the SRAM; and inferring, by the multi-layer perceptron, a probability corresponding to the read operation metric and computing a read access yield of the SRAM from the computed probability.

According to an aspect of the present embodiment, the read operation metric includes a voltage deviation of a pair of bit lines, an offset voltage of a sense amplifier, and a deviation of a detection time of the sense amplifier.

According to an aspect of the present embodiment, the computing, by the multi-layer perceptron, of the probability corresponding to the read operation metric is performed by inferring the probability based on that, from the design parameter of the SRAM, a distribution of the offset voltage of the sense amplifier follows a Gaussian distribution, and a distribution of the detection time of the sense amplifier follows a Gaussian distribution.

According to an aspect of the present embodiment, the multi-layer perceptron is trained with a matrix obtained by quantizing a voltage distribution of the bit line according to a threshold voltage deviation of a pull-down transistor and a pass transistor included in the SRAM, and the inferring, by the multi-layer perceptron, the probability corresponding to the read operation metric is performed by inferring the probability from the design parameter of the SRAM and the matrix obtained by quantizing the voltage distribution of the bit line.

The present embodiment includes a computing apparatus including: one or more processors; and a memory in which one or more programs to be executed by the one or more processors are stored, wherein the one or more programs that, when executed by the at least one processor, cause the one or more processors to perform a training method of training a multi-layer perceptron on a read access yield of a static random access memory (SRAM), wherein the training method includes: a first training operation of performing training with a design parameter of the SRAM according to a read operation metric of the SRAM, training data according to the read operation metric of the SRAM, and a transistor level simulation result of the SRAM; a second training operation of performing training with the design parameter of the SRAM according to the read operation metric of the SRAM, the training data according to the read operation metric of the SRAM, and a layout level simulation result of the SRAM; and a third training operation of performing training with the design parameter of the SRAM according to the read operation metric of the SRAM, the training data according to the read operation metric of the SRAM, and a measurement result measured with a chip in which the SRAM is formed.

The computing apparatus according to the present embodiment further performs a method of predicting a read access yield of the SRAM, the method including: inputting a transistor level simulation result of the SRAM, a layout level simulation result of the SRAM, and a measurement result measured with a chip in which the SRAM is formed into the multi-layer perceptron trained with the same design parameter of the SRAM and the same training data according to a read operation metric of the SRAM, together with the design parameter of the SRAM; inferring, by the multi-layer perceptron, a probability corresponding to the read operation metric; and computing a read access yield of the SRAM from the computed probability.

According to the present embodiment, unlike the related art, the yield of an SRAM is predicted without performing a simulation, so that a high productivity can be obtained, and despite nonlinear characteristics, the yield is predicted so that the productivity can be improved.

### BRIEF DESCRIPTION OF THE DRAWINGS

FIG. 1 is a diagram illustrating an overview of a training method of training a multi-layer perceptron on a static random access memory (SRAM) read access yield.

FIG. 2 is a block diagram illustrating an overview of a computing apparatus according to the present embodiment.

FIG. 3 is a diagram schematically illustrating the structure of an SRAM.

FIG. 4 is a diagram for describing read operation metrics related to a read operation yield of an SRAM.

FIGS. 5A and 5B are diagrams for describing the voltage difference distribution of a bit line and an inverted bit line of an SRAM.

FIGS. 6A and 6B are diagrams illustrating the voltage deviation of a bit line pair according to the fluctuations in the threshold voltage of a pass transistor and a pull-down transistor for each sensing window width of a sense amplifier.

FIG. 7A is a diagram illustrating changes in bit line voltage in three dimensions according to threshold voltages of a pass transistor and a pull-down transistor, and FIG. 7B is a diagram numerically illustrating changes in bit line voltage in a two-dimensional plane according to threshold voltages of a pass transistor and a pull-down transistor. FIG. 7C illustrates a probability distribution of the bit line voltage difference for all offset voltages.

FIG. 8 is a flowchart illustrating an overview of a method of inferring a yield with a trained multi-layer perceptron.

FIG. 9 is a diagram illustrating a yield predicted by inputting an SRAM design parameter into a multi-layer perceptron trained by a SRAM read access yield training method according to the present embodiment.

### DETAILED DESCRIPTION

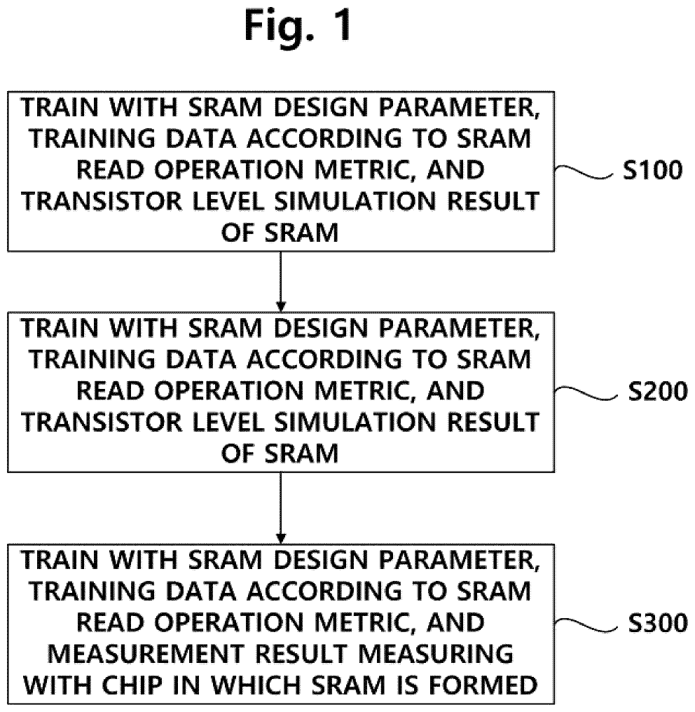

Hereinafter, the present embodiment will be described with reference to the accompanying drawings. FIG. 1 is a diagram illustrating an overview of a training method of training a multi-layer perceptron on a static random access memory (SRAM) read access yield. Referring to FIG. 1, the method of training a multi-layer perception on a read access yield of an SRAM includes: a first training operation (S100) of performing training with a design parameter of the SRAM according to a read operation metric of the SRAM, training data according to the read operation metric of the SRAM, and a transistor level simulation result of the SRAM; a second training operation (S200) of performing training with the design parameter of the SRAM according to the read operation metric of the SRAM, the training data according to the read operation metric of the SRAM, and a layout level simulation result of the SRAM; and a third training operation (S300) of performing training with the design parameter of the SRAM according to the read operation metric of the SRAM, the training data according to the read operation metric of the SRAM, and a measurement result measured with a chip in which the SRAM is formed.

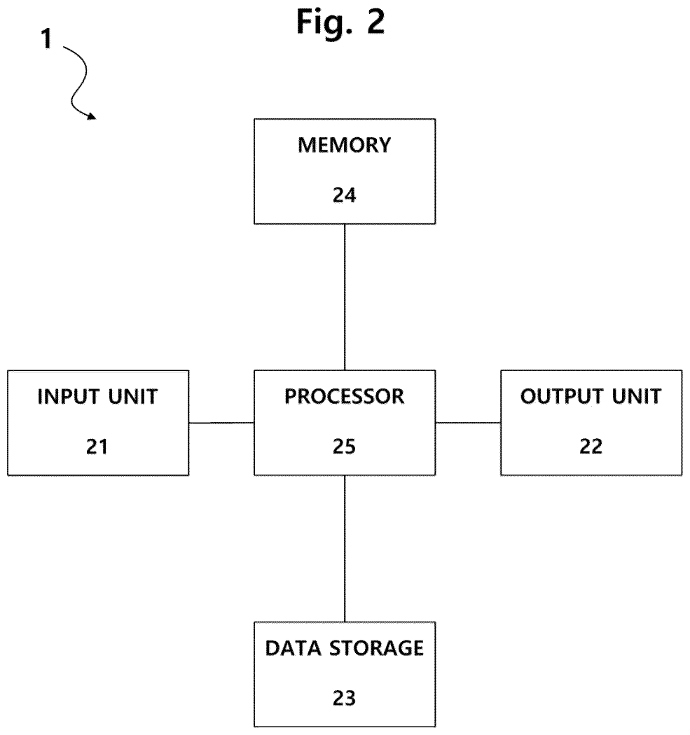

FIG. 2 is a block diagram illustrating an overview of a computing apparatus according to the present embodiment. Referring to FIG. 2, the computing apparatus 1 according to the present embodiment may include an input unit 21, an output unit 22, a processor 25, a memory 24, and a data storage 23. The computing apparatus 1 of FIG. 2 is illustrative of an embodiment, and all blocks shown in FIG. 2 are not essential components, and some blocks included in the computing apparatus 1 according to other embodiments may be added, changed or deleted. On the other hand, the computing apparatus 1 may be implemented as a computing apparatus that performs a training method, and each component included in the computing apparatus 1 may be implemented as a separate software device, or a separate hardware device combined with software.

The computing apparatus 1 may perform a first training operation (S100) of performing training with a design parameter of an SRAM, training data according to a read operation metric of the SRAM, and a transistor level simulation result of the SRAM, a second training operation (S200) of performing training with the design parameter of the SRAM, the training data according to the read operation metric of the SRAM, and a layout level simulation result of the SRAM, and a third training operation (S300) of performing training with the design parameter of the SRAM, the training data according to the read operation metric of the SRAM, and a measurement result measured with a chip in which the SRAM is formed.

In addition, the computing apparatus 1 may further perform a method of predicting a read access yield of an SRAM, and the method of predicting a yield of the SRAM includes: inputting a transistor level simulation result of the SRAM, a layout level simulation result of the SRAM, and a measurement result measured with a chip in which the SRAM is formed into a multi-layer perceptron trained with the same design parameter of the SRAM and the same training data according to a read operation metric of the SRAM, together with the design parameter of the SRAM; inferring, by the multi-layer perceptron, a probability corresponding to the read operation metric; and computing a read access yield of the SRAM from the computed probability.

The input unit 21 refers to a device that receives a design parameter of an SRAM, training data according to a read operation metric, and simulation results for each operation and/or user restriction conditions as an input. In addition, the input unit 21 may interact with the processor 25 to input various types of signals or data, or interact with an external device to directly acquire data and transfer the data to the processor 25. The input unit 21 may be a device or server for inputting log information, various types of condition information, control signals or the like, or receiving log information, various types of condition information, control signals or the like as an input, but is not limited thereto.

The output unit 22 may interact with the processor 25 to display training results, log information, and the like in each training operation. The output unit 22 may display various types of information through a display (not shown), a speaker, and the like provided in the computing apparatus 1 to output a predetermined piece of information, but is not limited thereto.

The processor 25 executes at least one command or program stored in the memory 24. The processor 25 according to the present embodiment computes data for performing each operation based on data acquired from the input unit 21 or the data storage 23, and detects a failure.

The memory 24 includes at least one command or program that may be executed by the processor 25. The memory 24 may fetch a command or program for performing a process stored in the data storage 23 and store the fetched command or program. The memory 24 may store associated values, such as results performed in each operation, intermediate values, and the like.

The data storage 23 refers to a general data structure implemented in a storage space (a hard disk or memory) of a computer system using a data management program (DBMS). The data storage 23 may freely perform data retrieval (extraction), deleting, editing, adding, and the like. In one embodiment, the data storage 23 may store instructions that are compiled to be driven as a chip segmentation method according to the present embodiment is performed by the processor 25. The memory 24 may fetch instructions at the request of the processor 25.

The data storage 23 according to the present embodiment may receive the SRAM design parameter, the training data according to the read operation metric, and the simulation results for each operation and/or the user restriction conditions that are provided through the input unit 21, and store the SRAM design parameters, the training data according to the read operation metric, and the simulation results for each operation and/or the user restriction conditions, and as needed, provide the stored data. On the other hand, the data storage 23 is described as being implemented in the computing apparatus 1, but is not limited thereto, and may be implemented as a separate data storage device.

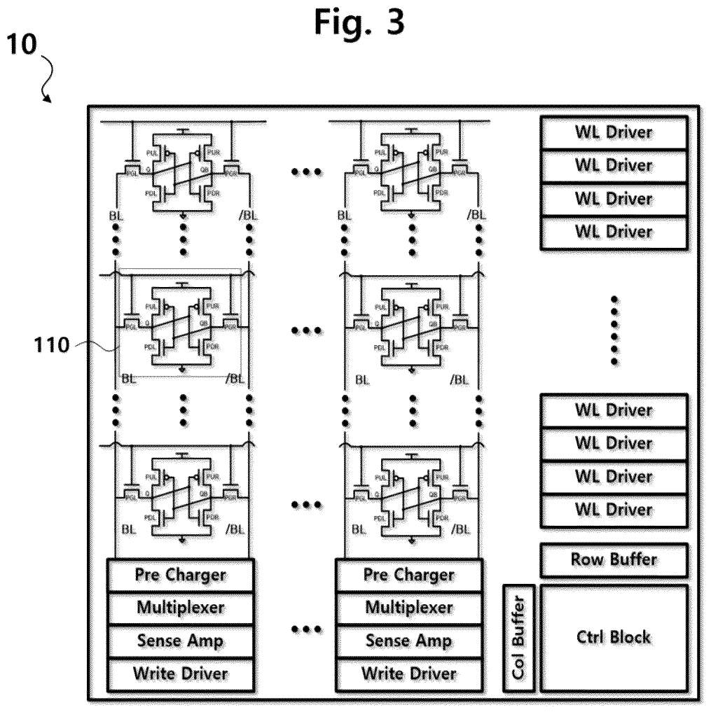

FIG. 3 is a diagram schematically illustrating the structure of an SRAM 10. Referring to FIGS. 1 to 3, the SRAM 10 includes a plurality of leaf cells. In one embodiment, the leaf cell may include a plurality of bit cells 110, a pre-charger Pre Charger for pre-charging a bit line BL and an inverted bit line/BL, a multiplexer Multiplexer, a sense amplifier Sense Amp, a write driver Write Driver, a word line driver WL Driver for driving a word line, a column buffer Col Buffer, a row buffer Row Buffer, and a controller Ctrl Block.

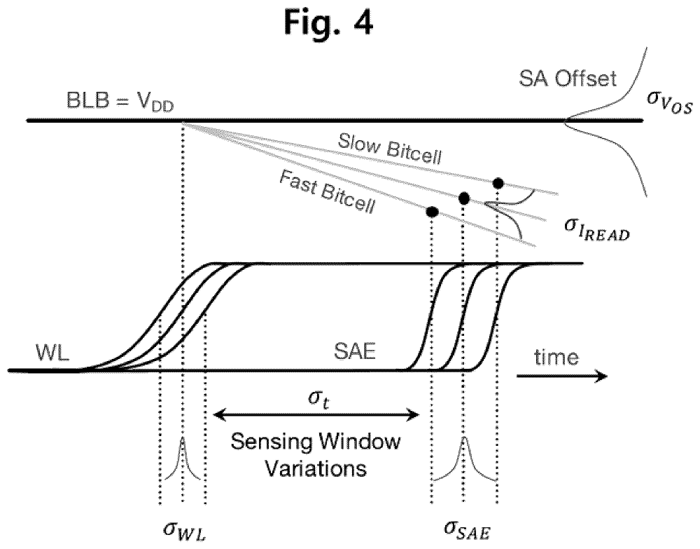

FIG. 4 is a diagram for describing read operation metrics related to a read operation yield of an SRAM. Referring to FIGS. 1 to 4, an SRAM may be related to several operations including data writing and data reading, and each of the operations may be associated with a number of operation metrics. Among the metrics, read operation metrics associated with an SRAM read operation include an offset voltage deviation of the sense amplifier Sense Amp, a sensing window width deviation of the sense amplifier Sense Amp, and a deviation of a voltage difference (V_{BL}, a bit line voltage difference) of the bit line BL and the inverted bit line/BL (hereinafter referred to as a voltage deviation of a bit line pair).

As illustrated by FIG. 4, the voltage deviation of the bit line pair occurs due to a difference in the times of discharging charges charged on a bit line and an inverted bit line in each bit cell, and as will be described below, and is greatly influenced by a pass transistor and a pull-down transistor included in the bit cell 110, and the voltage difference deviation of the bit lines does not follow a Gaussian distribution.

As shown in the drawing, the sensing window width deviation of the sense amplifier refers to the difference in the times taken for the sense amplifier to detect the voltage difference formed on the bit line, and the voltage offset deviation of the sense amplifier refers to the difference in voltages formed on a bit line side and an inverted bit line side of the sense amplifier. The sensing window width deviation and the voltage offset deviation of the sense amplifier follow a Gaussian distribution.

The multi-layer perceptron is trained with training data according to a read operation metric of the SRAM, a design parameter of the SRAM according to a read operation metric of the SRAM, and a transistor level simulation result of the SRAM (S100). In one embodiment, an SRAM designed according to the input design parameter is subject to a simulation at a transistor level to acquire simulation results, and the multi-layer perceptron is trained with the simulation results together with the input design parameter.

In one embodiment, the multi-layer perceptron may be trained with the SRAM design parameter associated with the read operation metric, and the SRAM design parameter may be design parameters of the leaf cells described above. For example, the design parameters of the sense amplifier may include the size of a pull down transistor of the sense amplifier, the size of a pull-up transistor of the sense amplifier, the size of a pass transistor of the sense amplifier, and the size of a sense amplifier foot.

For example, the design parameters of the bit cell may include a channel width of a pull-up transistor of the bit cell, a channel width of a pull-down transistor of the bit cell, a pass channel width of the bit cell, and the like.

Read operation metrics associated with an SRAM read operation include the voltage offset deviation of the sense amplifier Sense Amp, the sensing window width deviation of the sense amplifier Sense Amp, and the voltage difference deviation of the bit line, and the voltage offset deviations of the sense amplifier Sense Amp follow a Gaussian distribution. Therefore, a simulation is performed with design parameters, and training data is generated with a mean and a standard deviation of voltage offset deviations of the sense amplifier. In one embodiment, the training data on the offset voltage deviation of the sense amplifier may be a probability distribution of offset voltage deviations computed as a mean and a standard deviation of the offset voltage deviations.

As described above, the sensing window width deviations of the sense amplifier Sense Amp follow a Gaussian distribution. Therefore, a simulation is performed with design parameters, and training data is generated with a mean and a standard deviation of sensing window width deviations of the sense amplifier. In one embodiment, the training data on the sensing window width deviation of the sense amplifier Sense Amp may be a probability distribution of sensing window widths computed as a mean and a standard deviation of sensing window width deviations.

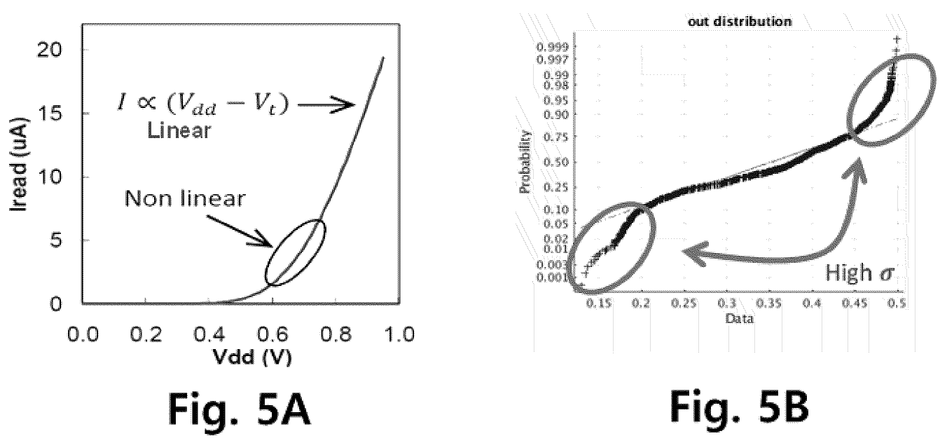

FIGS. 5A and 5B are diagrams for describing the voltage difference distribution of a SRAM bit line pair, and FIG. 5B is an enlarged view of an area indicated by a black ellipse on FIG. 5A. Referring to FIG. 5A, the conventional SRAMs operate in an area in which the current is linear with respect to the driving voltage V_{DD}. However, as transistors are miniaturized and the driving voltage of transistors decrease, SRAMs operate in a nonlinear region illustrated in FIGS. 5A and 5B, and such a nonlinear bit line voltage difference does not follow a Gaussian distribution.

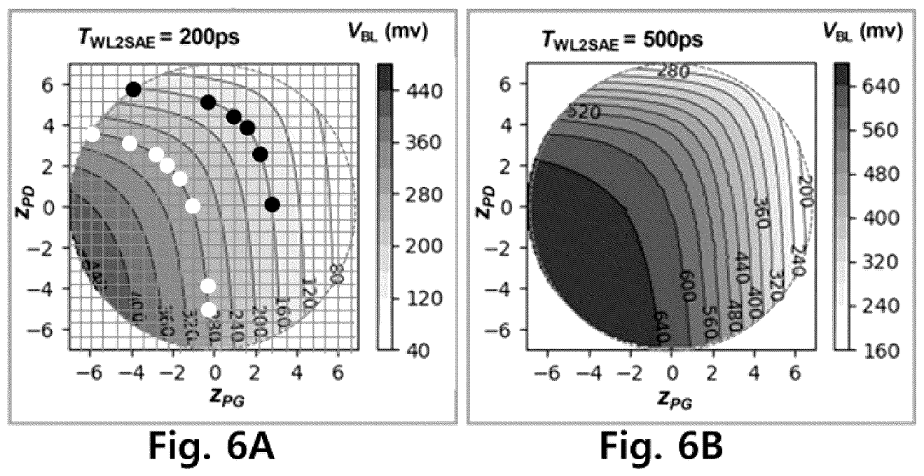

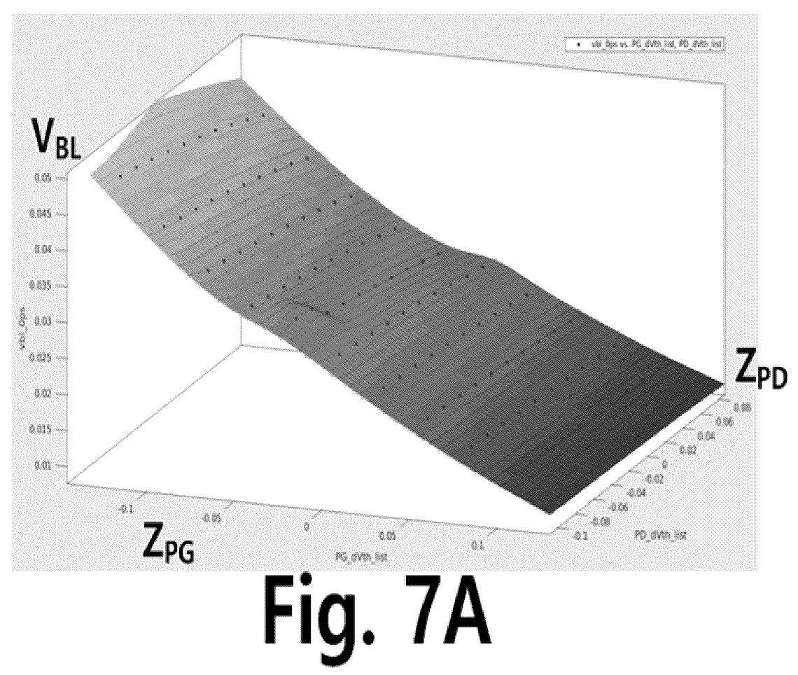

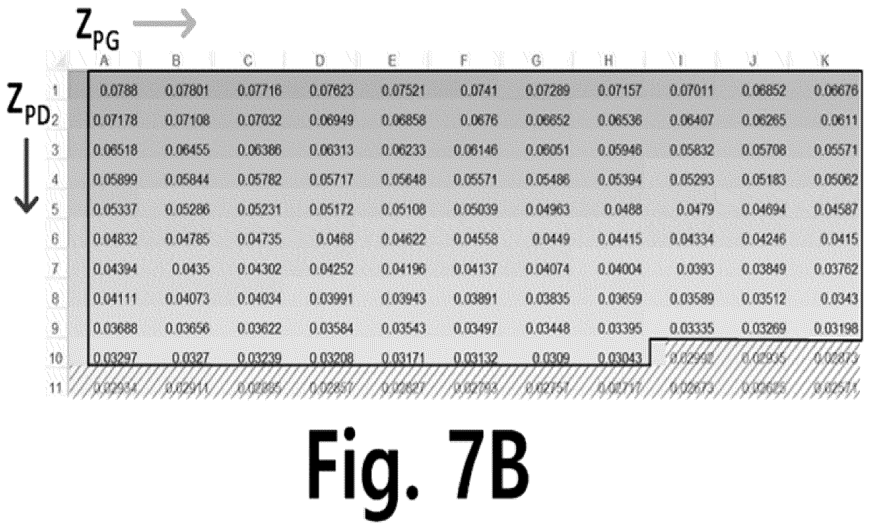

FIGS. 6A and 6B are diagrams illustrating the bit line voltage deviation according to the fluctuations in the threshold voltage of a pass transistor (PGL or PGR in FIG. 3) and a pull-down transistor (PDL or PDR in FIG. 3) for each sensing window width of a sense amplifier Sense Amp. Referring to FIG. 6A, the horizontal axis represents a threshold voltage distribution of a pass transistor from −6σ to 6σ (σ: standard deviation), and the vertical axis represents a threshold voltage distribution of a pull-down transistor from −6σ to 6σ. However, the range does not limit the scope of the present invention, and those skilled in the art may generate training data by performing measurement in a range broader or narrower than the range of −6σ to 6σ without being limited to the range of −6σ to 6σ.

FIG. 6A is a diagram obtained by plotting points having the same bit line voltage deviation in the same color at grid points formed by threshold voltages of a pass transistor and threshold voltages of a pull-down transistor when the sensing window width of the sense amplifier Sense AMP is 200 psec. It can be seen that the distribution of bit line voltage deviations forms a nonlinear distribution.

FIG. 6B is a diagram obtained by plotting points having the same bit line voltage deviation in the same color at grid points formed by threshold voltages of a pass transistor and threshold voltages of a pull-down transistor when the sensing window width of the sense amplifier Sense AMP is 500 psec. As shown in FIGS. 6A and 6B, it can be seen that the voltage deviation of the bit line pair has a nonlinear characteristic, and as the width of the sensing window increases, the voltage deviation of the bit line pair increases.

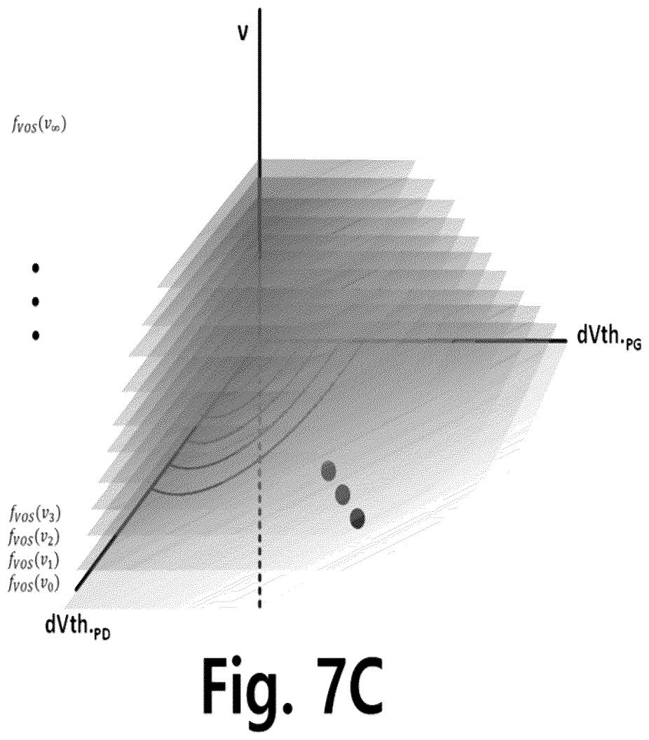

FIG. 7A is a diagram illustrating changes in voltage deviation of a bit line pair in three dimensions according to threshold voltages of a pass transistor and a pull-down transistor, and FIG. 7B is a diagram numerically illustrating changes in voltage deviation of a bit line pair in a two-dimensional plane according to threshold voltages of a pass transistor and a pull-down transistor. In one example, in order to compute the probability of the voltage deviation of the bit line pair being greater than or equal to 30 mv, an area in which the bit line voltage less than 30 mv, such as the hatched portion in FIG. 7B, is removed, so that a portion shown in a solid line remains

The horizontal axis represents a change in the threshold voltage of the pass transistor, which follows a Gaussian distribution. The vertical axis represents a change in the threshold voltage of the pull-down transistor, which also follows a Gaussian distribution.

Therefore, since the mean and the standard deviation are already known, the probability value of elements included in each row and each column may be identified. As described above, the probability value of a slice having a bit line voltage difference of 30 my may be identified in FIG. 7C. However, the slice corresponds to a case when the offset voltage is 30 mv, and considering that the distribution of the offset voltage also follows a Gaussian distribution, the probability of the offset voltage being 30 my is obtained, and multiplied so that the probability of the slice may be obtained.

Thus, the probabilities of all slices are obtained and integrated, thereby obtaining a probability distribution of the bit line voltage difference for all offset voltages illustrated in FIG. 7C. The process described above corresponds to the terms expressed in the brackets in Equation 1 below. By using the probability distribution of the bit line voltage difference obtained as described above as training data, the multi-layer perceptron is trained.

In one embodiment, the yield may be computed with the probability distribution of the offset voltage deviation of the sense amplifier, the probability distribution of the sensing window width of the sense amplifier, and the probability distribution of the voltage deviation of the bit line pair, and the multi-layer perceptron may be trained using the yield as training data. Equation 1 is an equation for computing a yield.

$${Y}_{R} = {\int }_{{T}_{WL 2 SAE}} {[ {\int }_{{V}_{OS}} {\{ 1 - {F}_{VBL} ( v \vert {T}_{WL 2 SAE} = 1 ) \}}^{{N}_{ROW} {N}_{COL , SA}} {f}_{VOS} ( v ) dv ]}^{{N}_{SA}} \times {f}_{TWL 2 SAE} ( t ) dt . \qquad [ Equation 1 ]$$

In Equation 1 described above, F_{VBL}(V|T_{WL2SAE}=t) denotes the probability that data is not detected when the sensing window width is t and the voltage deviation of the bit line pair is v. Thus, 1−F_{VBL}(V|T_{WL2SAE}=t) denotes the probability that a voltage deviation of the bit line pair occurs such that data is detectable by the sense amplifier.

In addition, from the probability distribution of the offset voltage deviations of the sense amplifier, the probability f_{VOS}(v) that the sense amplifier detects data at an offset voltage is obtained and multiplied by the term F_{VBL}(V|T_{WL2SAE}=t) and integrated, and from the probability distribution of the sensing window widths, the probability f_{TWL2SAE}(t) that data is detected within a detection time of the sense amplifier is obtained, multiplied by the above, and integrated to thereby obtain the yield. The yield computed as describe above is used as training data with which the multi-layer perceptron may be trained.

The multi-layer perceptron is trained using training data obtained by performing a layout level simulation based on design parameters (S200). In operation S200, the multi-layer perceptron is trained using a result obtained by performing a layout level simulation using the same parameter as the design parameter for performing the transistor level simulation. The layout level simulation is performing a simulation on a result obtained by laying out transistors directly by the designer or using an automated tool. The layout level simulation may simulate even the impact of parasitic resistances and/or parasitic capacitances by the effects of metal wires, vias, and the like.

Therefore, the layout level simulation may be performed with the same design parameter as that described above to obtain probability distributions, which are training data. Similarly, through the obtained probability distributions, the above-described Equation 1 may be computed to obtain the yield, and the obtained yield may be used as training data with which the multi-layer perception may be trained.

As the multi-layer perceptron trained with the training data obtained from the transistor level simulation is trained with the training data obtained from the layout level simulation, a layer for the impact of parasitic resistances and/or parasitic capacitances, which is a simulation result obtained at the layout level, may be further formed as a hidden layer. This can be seen from the difference between a result of predicting a yield through the multi-layer perceptron completed with the transistor level simulation and a result of predicting a yield through the multi-layer perceptron completed with the layout level simulation while using the same training parameter.

Subsequently, a chip formed with the design parameter is manufactured, and the multi-layer perceptron is trained using training data obtained by performing measurement using the chip (S300). In operation S300, the multi-layer perceptron is trained using a result obtained by performing measurement using the chip, which is formed with the same design parameter as the design parameter for performing the transistor level simulation. The chip level measurement obtains data by performing a measurement on a SRAM chip formed with actual chips. Accordingly, the uncertainty that has occurred in actual chips may be reflected.

The data obtained by the measuring from the chip may provide an impact of process variables in a process of forming a layout with actual chips. Therefore, probability distributions, which serve as training data, may be obtained from chips manufactured with the same design parameter as that described above. Similarly, through the obtained probability distributions, the above-described Equation 1 may be computed to obtain the yield, and the obtained yield may be used as training data with which the multi-layer perception may be trained.

As the multi-layer perceptron trained with the training data obtained from the layout level simulation is trained with the training data obtained by measuring actual chips, a layer on the impact of process variations may be further formed as a hidden layer. This can be seen from the difference between a result of predicting a yield through the multi-layer perceptron completed with the layout level simulation and a result of predicting a yield through the multi-layer perceptron trained with the training data obtained by measuring actual chips while using the same training parameters.

In one embodiment, the multi-layer perceptron may be provided with the computed yield as training data and thus learn the yield. The yield learned by the multi-layer perceptron may be used as a guide value for fitting a yield computed when inferring and predicting a yield.

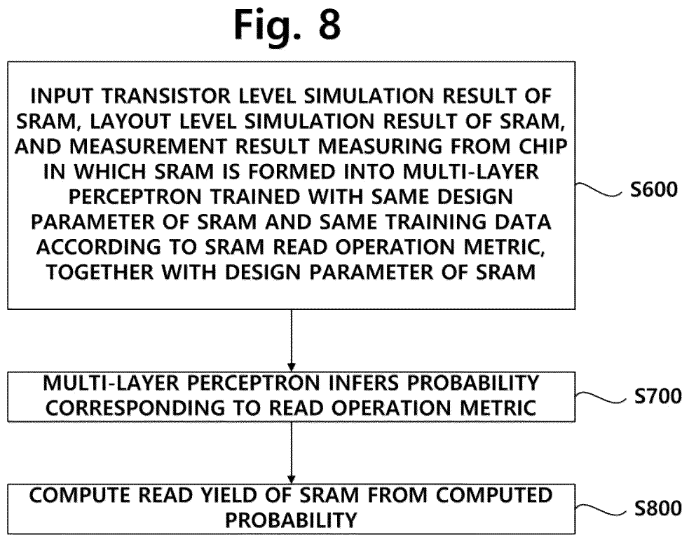

FIG. 8 is a flowchart illustrating an overview of a method of inferring a yield with a trained multi-layer perceptron. Referring to FIG. 8, a method of predicting a read access yield of an SRAM with a trained multi-layer perceptron according to the present embodiment includes: inputting a transistor level simulation result of the SRAM, a layout level simulation result of the SRAM, and a measurement result measured with a chip in which the SRAM is formed into a multi-layer perceptron trained with the same design parameter of the SRAM and the same training data according to a read operation metric of the SRAM, together with the design parameter of the SRAM (S600); inferring, by the multi-layer perceptron, a probability corresponding to a read operation metric (S700); and computing a read access yield of the SRAM from the computed probability (S800).

As described above, the multi-layer perceptron is trained with the transistor level simulation result of the SRAM, the layout level simulation result of the SRAM, and the measurement result measured with the chip in which the SRAM is formed, based on the same SRAM design parameter.

When the design parameter is input to the multi-layer perceptron, the multi-layer perceptron infers the probability corresponding to a read operation metric corresponding to the input design parameter. In one embodiment, the read operation metric may include an offset voltage deviation of the sense amplifier, a sensing window width deviation of the sense amplifier, and a voltage deviation of the bit line pair.

The multi-layer perceptron may output the probability distribution of the offset voltage deviation of the sense amplifier from the design parameter provided as the input, and may output the probability distribution of the sensing window width of the sense amplifier. In addition, the multi-layer perceptron outputs the probability distribution of the bit line voltage difference for the offset voltage from the design parameter provided as the input (S700).

Subsequently, the read access yield of the SRAM is computed from the computed probability (S800). In one embodiment, the read access yield may be computed by the multi-layer perceptron, but may be performed by other computing apparatuses.

In one embodiment, the yield may be computed from the above-described Equation 1. In other words, in Equation 1 described above, F_{VBL}(V|T_{WL2SAE}=t) denotes the probability that data is not detected when the sensing window width is t and the voltage deviation of the bit line pair is v. Thus, 1−F_{VBL}(V|T_{WL2SAE}=t) denotes the probability that a bit line voltage difference occurs such that data is detectable by the sense amplifier.

In addition, from the probability distribution of the offset voltage deviations of the sense amplifier, the probability f_{VOS}(v) that the sense amplifier detects data at an offset voltage is obtained and multiplied by the term 1−F_{VBL}(V|T_{WL2SAE}=t) and integrated, and from the probability distribution of the sensing window widths, the probability that data is detected within a detection time of the sense amplifier is obtained, multiplied by the above, and then integrated to thereby obtain the yield. The yield may be calculated as described above.

In one embodiment, the computed yield may be learned by the multi-layer perceptron, and the learned yield may be used as a guide value for fitting a yield computed in a yield inference.

### Simulation Example

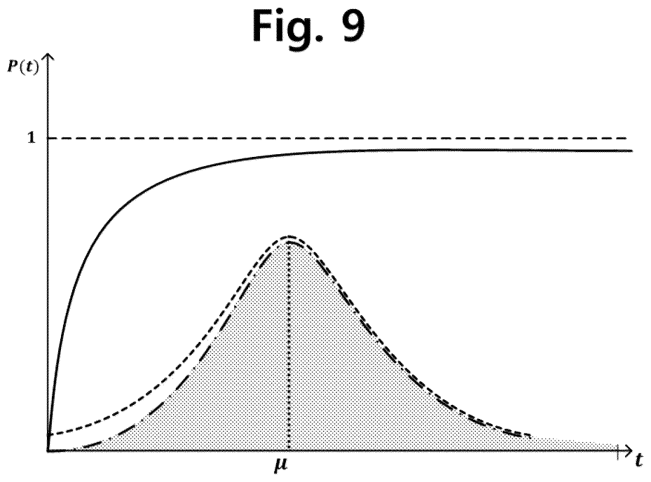

FIG. 9 is a diagram illustrating a yield predicted by inputting an SRAM design parameter into a multi-layer perceptron trained by a SRAM read access yield training method according to the present embodiment. Referring to FIG. 9, a solid line is a plot representing a result obtained by multiplying the probability that a voltage deviation of a bit line pair has occurred to a level at which data is detectable by the sense amplifier by the probability that data is detected by the sense amplifier at an offset voltage, and integrating the multiplication results.

In FIG. 9, a dashed line represents a probability distribution of sensing window widths. As described above, it can be seen that the distribution has a Gaussian distribution. The probability distribution indicated by the dashed line is multiplied by the probability indicated by the solid line, thereby obtaining a dashed-dotted line, which corresponds to an envelope of a read access yield.

Thus, by performing integration along the read access yield envelope, a target read access yield may be obtained.

Although embodiments of the present invention have been described with reference to the accompanying drawings, this is for illustrative purposes, and those of ordinary skill in the art should appreciate that various modifications, equivalents, and other embodiments are possible without departing from the scope and sprit of the present invention. Therefore, the scope of the present invention is defined by the appended claims of the present invention.

1. A static random access memory (SRAM) read access yield training method that is a method of training a multi-layer perceptron on a read access yield of an SRAM, the method comprising:
a first training operation of performing training with a design parameter of the SRAM according to a read operation metric of the SRAM, training data according to the read operation metric of the SRAM, and a transistor level simulation result of the SRAM;
a second training operation of performing training with the design parameter of the SRAM according to the read operation metric of the SRAM, the training data according to the read operation metric of the SRAM, and a layout level simulation result of the SRAM; and
a third training operation of performing training with the design parameter of the SRAM according to the read operation metric of the SRAM, the training data according to the read operation metric of the SRAM, and a measurement result measured with a chip in which the SRAM is formed.

2. The method of claim 1, wherein, as a result of the second training operation, a layer reflecting an effect of one or more of a parasitic resistance and a parasitic capacitance is generated in the multi-layer perceptron.

3. The method of claim 1, wherein, as a result of the third training operation, a layer reflecting an effect of a process is generated in the multi-layer perceptron.

4. The method of claim 1, wherein the read operation metric includes a voltage deviation of a bit line pair, an offset voltage of a sense amplifier, and a detection time deviation of the sense amplifier.

5. The method of claim 4, wherein training data according to the voltage deviation of the bit line pair is acquired from a probability distribution of a threshold voltage of a pass transistor of the SRAM, a probability distribution of a threshold voltage of a pull-down transistor of the SRAM, and a probability of a bit line voltage value.

6. The method of claim 5, wherein training data according to the offset voltage of the sense amplifier and the detection time deviation of the sense amplifier includes:
a probability distribution computed as a mean and a standard deviation of offset voltage deviations of the sense amplifier following a Gaussian distribution; and
a probability distribution computed as a mean and a standard deviation of detection time deviations of the sense amplifier following a Gaussian distribution.

7. The method of claim 6, wherein the training data further includes a yield value computed by
$${Y}_{R} = {\int }_{{T}_{WL 2 SAE}} {[ {\int }_{{V}_{OS}} {\{ 1 - {F}_{VBL} ( v \vert {T}_{WL 2 SAE} = 1 ) \}}^{{N}_{ROW} {N}_{COL , SA}} {f}_{VOS} ( v ) dv ]}^{{N}_{SA}} \times {f}_{TWL 2 SAE} ( t ) dt ,$$
wherein F_{VBL}(V|T_{WL2SAE}=t) is a probability that no voltage deviation occurs in the bit line pair as much as the offset voltage of the sense amplifier during the detection time of the detection amplifier,
f_{VOS}(v) is a probability that the sense amplifier succeeds in detection at an offset voltage, and
f_{TWL2SAE}(t) is a probability that sensing is successful within a detection time of the sense amplifier.

8. A static read only memory (SRAM) read access yield prediction method using a trained multi-layer perceptron, the method comprising:
inputting a transistor level simulation result of the SRAM, a layout level simulation result of the SRAM, and a measurement result measured with a chip in which the SRAM is formed into the multi-layer perceptron trained with the same design parameter of the SRAM and the same training data according to a read operation metric of the SRAM, together with the design parameter of the SRAM;
inferring, by the multi-layer perceptron, a probability corresponding to the read operation metric; and
computing a read access yield of the SRAM from the computed probability.

9. The method of claim 8, wherein the read operation metric includes a voltage deviation of a pair of bit lines, an offset voltage of a sense amplifier, and a deviation of a detection time of the sense amplifier.

10. The method of claim 9, wherein the computing, by the multi-layer perceptron, of the probability corresponding to the read operation metric is performed by inferring the probability that, from the design parameter of the SRAM, a distribution of the offset voltage of the sense amplifier follows a Gaussian distribution, and a distribution of the detection time of the sense amplifier follows a Gaussian distribution.

11. The method of claim 9, wherein the multi-layer perceptron is trained with a matrix obtained by quantizing a voltage distribution of the bit line according to a threshold voltage deviation of a pull-down transistor and a pass transistor included in the SRAM, and
the inferring, by the multi-layer perceptron, the probability corresponding to the read operation metric is performed by inferring the probability from the design parameter of the SRAM and the matrix obtained by quantizing the voltage distribution of the bit line.

12. A computing apparatus comprising:
at least one processor; and
a memory in which one or more programs to be executed by the at least one processor are stored, wherein the one or more programs, when executed by the at least one processor, cause the at least one processor to perform a training method of training a multi-layer perceptron on a read access yield of a static random access memory (SRAM), wherein the training method includes:
a first training operation of performing training with a design parameter of the SRAM according to a read operation metric of the SRAM, training data according to the read operation metric of the SRAM, and a transistor level simulation result of the SRAM;
a second training operation of performing training with the design parameter of the SRAM according to the read operation metric of the SRAM, the training data according to the read operation metric of the SRAM, and a layout level simulation result of the SRAM; and
a third training operation of performing training with the design parameter of the SRAM according to the read operation metric of the SRAM, the training data according to the read operation metric of the SRAM, and a measurement result measured with a chip in which the SRAM is formed.

13. The computing apparatus of claim 12, wherein the computing apparatus further performs a method of predicting a read access yield of the SRAM, the method comprising:
inputting a transistor level simulation result of the SRAM, a layout level simulation result of the SRAM, and a measurement result measured with a chip in which the SRAM is formed into the multi-layer perceptron trained with the same design parameter of the SRAM and the same training data according to a read operation metric of the SRAM, together with the design parameter of the SRAM;
inferring, by the multi-layer perceptron, a probability corresponding to the read operation metric; and
computing a read access yield of the SRAM from the computed probability.
